(19) United States
(12) Patent Application Publication
(10) Pub. No.: US 2020/0300894 A1
(43) Pub. Date: Sep. 24, 2020

(54) CURRENT SENSOR ASSEMBLY

(71) Applicant: Sensitec GmbH, Lahnau (DE)

(72) Inventors: Matthias Brusius, Hartenrod (DE); Claudia Glenske, Leungermany (DE)

(21) Appl. No.: 16/650,490

(22) PCT Filed: Mar. 20, 2018
(86) PCT No.: PCT/EP2018/056972

§ 371 Date: Mar. 25, 2020

(30) Foreign Application Priority Data
Oct. 12, 2017 (DE) 10 2017 123 785.2

(51) Int. Cl. G01R 15/20; G01R 19/00

(52) U.S. Cl. CPC G01R 15/205; G01R 19/0092; G01R 15/207

(57) ABSTRACT

A current sensor assembly includes a magnetoresistive gradient sensor which is arranged between two conductor portions of a current conductor. The conductor portions subdivide the current and carry it in the same direction with regard to the arrangement of the magnetoresistive gradient sensor, and the conductor portions are height-offset with regard to a measurement plane of the magnetoresistive gradient sensor.

### CROSS-REFERENCE TO RELATED APPLICATIONS

This application is the U.S. national stage of PCT/EP2018/056972 filed Mar. 20, 2018, which claims priority of German Patent Application 10 2017 123 785.2 filed Oct. 12, 2017 both of which are hereby incorporated by reference in their entirety.

### FIELD OF THE INVENTION

The present invention relates to a current sensor assembly for measuring a current through a conductor on the basis of the magnetic field surrounding the conductor.

### BACKGROUND OF THE INVENTION

The invention relates to a magnetic field sensor device for measuring the intensity of a current through one or more conductors based on the magnetic field surrounding the conductor.

Magnetic field sensor devices for measuring the intensity of a current through one or more conductors on the basis of the magnetic field H along a closed curve S and surrounding the conductor are sufficiently well known in the art. They are based on the fact that it is possible to draw a conclusion as to the total current/passing through the area A bounded by the curve S, according to Ampere's Law:

$$I = \int {\int }_{A} {J}^{->} \cdot d {A}^{->} = {\int }_{S} • { }^{->} H \cdot d {s}^{->}$$

This allows contactless current detection without intervention in the operation of an electrical circuit, in particular without interruption or interposition of an electrical circuit.

Assemblies are known from the prior art which use magnetoresistive gradient sensors to measure a magnetic field strength difference in a measurement plane between conduction currents of adjacent current conductors.

The magnetic field-sensitive sensor elements generally used are magnetoresistive sensor elements which operate, for example, using the Hall, AMR, GMR or TMR effect.

Such magnetoresistive gradient sensors may for instance take the form of two magnetic field sensors based for example on an xMR technology such as AMR, TMR or GMR, wherein the respective magnetic field sensors detect the magnetic field caused by each current part and the magnetic field sensors internally or externally determine a gradient value therefrom. TMR and GMR sensors are based on the TMR or GMR effect and consist of various thin layers just a few nanometres thick and made of soft magnetic, nonmagnetic, metallic and hard magnetic materials. The alignment between the soft and hard magnetic layers is crucial for the resistance value, which changes with the change in angle of the magnetic field.

If two sensor elements are placed spacedly next to one another, the sensor may be made robust against external interference fields by differential evaluation of the sensor signals. The difference quotient is understood to be a gradient of the magnetic field. These gradient sensors are particularly suitable for example for position measuring systems and current sensors.

The sensor element is arranged in the region of the conductor portion active in terms of current measurement, in such a way that the magnetic field of the conductor portion active in terms of current measurement brings about a major sensor value change, in particular a major resistance change, and the magnetic field of the conductor portion parasitic in terms of current measurement brings about minor or substantially no sensor value changes, due to the spatial orientation of the sensor element relative to the conductor portion parasitic in terms of current measurement and/or as a result of field compensation effects of further current-carrying elements.

For the purposes of the invention, the gradient sensor may take the form of a gradient interconnection of magnetoresistive resistance elements of an individual sensor assembly; it is also possible for the purposes of the invention for two magnetic field sensors to be provided, which each detect the magnetic field of one current conductor portion, and which are calculated externally to yield a gradient value.

Previous solutions for current measurement in gradiometer assemblies are generally based on U-shaped bus bars for producing a primary current-dependent field gradient. To this end, a current flowing in both legs of the U-shaped conductor portion is considered, wherein the current flowing into one leg and out in the neighbouring leg forms a superposed overall magnetic field between the legs, the field gradient of which is detected in a measurement plane. Naturally, the same amount of current flows in both legs, but in opposing directions.

A disadvantage of the prior art in the field of current measurement in the gradiometer assembly is that the inductance formed by the U-shaped current legs may lead, in particular in the case of relatively high frequencies, to voltage peaks, something which has to be compensated by a switched-in power semiconductor electronics unit, which is designed for example for converter operation. This must thus be designed for such relatively high voltage peaks.

Furthermore, with increasing miniaturisation of such a current sensor, interference field components may, for example as a result of currents in the connecting web between the legs of the U-shaped conductor, assume a magnitude which leads to a change in the magnetisation of the magnetic field-sensitive layers of the xMR sensor.

Furthermore, the manufacture of U-shaped conductor legs entails relatively significant manufacturing effort and material scrap. Furthermore, the total current flows through the legs in high current assemblies, such that the legs have to have a high current carrying capacity.

Moreover, a skin effect arises if a high frequency alternating current flows through a conductor, wherein the current density is lower in the inner regions of the conductor than in the outer regions due to a current displacement effect. This means that, in the case of alternating current, eddy currents and electrical fields are generated as a function of frequency which displace the charge carriers to the surface of the conductor.

In addition, a proximity effect acts between two closely adjacent conductors. The proximity effect is a current displacement phenomenon, wherein this frequency-dependent phenomenon is limited to eddy currents between closely adjacent conductors in which alternating currents flow in opposing directions, as is the case with the previously known current measuring sensors with U-shaped conductor elements. According to the proximity effect, which is particularly pronounced at higher frequencies, high frequency currents tend to flow as closely as possible to one another. The current flow is concentrated onto the region in which the two conductors lie closely next to one another.

In the case of the U-shaped conductor loop, superimposition of the two above-stated effects brings about a high current density in the inner regions of the legs, in particular in the edges. High frequency currents are thus carried markedly more densely and the field gradient rises in the region of the sensor. In this respect, the previously known U-shaped current sensors are dependent on current frequency with regard to their measurement quality.

Finally, a disadvantageous parasitic effect of feed line and current loop arises. A generic U-shaped assembly for magnetic field-based measurement of electrical currents comprises at least one conductor portion active in terms of current measurement and at least one conductor portion parasitic in terms of current measurement. The conductor portion parasitic in terms of current measurement corresponds to the feed line or current loop. On passage of the current, parasitic magnetic fields are brought about by the conductor portions parasitic in terms of current measurement. The parasitic magnetic fields which are brought about have an influence on the measured values of the magnetic field-sensitive sensor element.

To summarise, prior solutions for current measurement in a gradiometer assembly on the basis of U-shaped bus bars have the following disadvantages: a current flowing in both legs of the U-shaped conductor portion is considered, wherein the current flowing into one leg and out in the neighbouring leg forms a superposed overall magnetic field between the legs, the field gradient of which is detected in a measurement plane. Naturally, the same amount of current flows in both legs. The following disadvantages result:

large effective cross-section and difficult thermal dimensioning interference fields due to deflection/feedback high leakage inductance (disadvantageous for switching behaviour in power semiconductors) large installation space strong frequency dependence due to skin and proximity effects unfavourable arrangement for capacitive and inductive interference injection in conventional manufacturing methods, large quantity of scrap bus bar material.

The inductance formed by the U-shaped current legs leads to voltage peaks, something which has to be compensated by a switched-in power semiconductor electronics unit, which is designed for example for converter operation. This must thus be designed for relatively high voltage peaks.

Furthermore, the manufacture of U-shaped conductor legs entails relatively significant manufacturing effort and material scrap.

Specifically with high current assemblies, the total current flows through the legs, which have to have a high current carrying capacity.

DE 101 10 254 A1 discloses a current sensor which serves in potential-free current measurement in the higher frequency range. Limitations in terms of the frequency-independence of the magnetic fields result if highly conductive materials in any geometric shape are present in the vicinity of the circular current conductor. The induction of eddy currents in these materials, and the effect thereof, gives rise to a non-circular symmetrical current distribution in the current conductors and thus a frequency dependence of the magnetic field at the location of the sensor which may lead to measurement errors in current determination, which may emerge due to the “skin” and “proximity” effects. In this document, the current sensor is constructed from one or more electrically parallel- or series-connected current conductors and magnetic field sensors or magnetic field gradient sensors. On passage of current, the magnetic field surrounding a current conductor or a plurality of conductors is measurable by magnetic field sensors or magnetic field gradient sensors, wherein currents in each case flow over the current sensor in opposite directions. The output signal of the respective sensor is frequency-dependent in the intended range. The current conductors are shaped such that a magnetic field change arising at the location of the respective sensor suppresses the formation of eddy currents. In this way, the potential-free current is intended to be measurable with the current sensor in the higher frequency range with a low level of measurement error.

WO 2014/001473 A1 shows a further assembly for current measurement. For magnetic field-based measurement of electrical currents by means of at least one magnetic field-sensitive sensor element, the assembly is proposed to take the form of an angled, in particular U-shaped conductor element, which comprises at least one conductor portion active in terms of current measurement and at least one conductor portion parasitic in terms of current measurement. The sensor element has at least one sensitivity direction, in which magnetic field components bring about a significant sensor value change, wherein the sensor element is oriented in such a way in the region of the conductor portion active in terms of current measurement, in particular is rotated, tilted and/or height-offset relative to the conductor portion parasitic in terms of current measurement, that the magnetic field of a conductor portion active in terms of current measurement of the U-shaped conductor element is oriented substantially in the sensitivity direction and the magnetic field of a conductor portion parasitic in terms of current measurement of the U-shaped conductor element is oriented substantially not in the sensitivity direction, in particular at right angles to the sensitivity direction.

On the basis of the above-stated prior art, the object of the invention is to reduce the disadvantages of known assemblies.

The above-stated disadvantages are solved by an assembly as described herein. Advantageous further developments of the invention are also described.

### SUMMARY OF THE INVENTION

A current sensor assembly is proposed which comprises a magnetoresistive gradient sensor, wherein the magnetoresistive gradient sensor is arranged between two conductor portions of a current conductor of the magnetoresistive gradient sensor.

According to the invention, it is proposed that the conductor portions subdivide the current and carry it in the same direction with regard to the arrangement of the magnetoresistive gradient sensor, and that the conductor portions are height-offset with regard to a measurement plane of the magnetoresistive gradient sensor. In other words, the current conductor is offset in two planes relative to the measurement plane without cross-paths of conductor portions. The measurement plane of the magnetoresistive gradient sensor is the plane in which a gradient field is measured by magnetoresistive resistors of the sensor assembly. The gradient field is here parallel to the measurement plane. The two conductor portions of the same current conductor, which is separated in practice, are height-offset relative to the measurement plane of the magnetoresistive gradient sensor. Both conductor portions carry current in the same direction with regard to the magnetoresistive gradient sensor. The current component in the first conductor portion generates a magnetic field. Similarly, the current generates another magnetic field in the second conductor portion. Both magnetic fields surround the conductor portions in the same direction according to the right-hand rule. With regard to the measurement plane, components of the magnetic field oriented normal thereof are opposingly oriented in each of the two conductor portions, and a tangential component, located in the measurement plane, of the magnetic field is likewise opposingly oriented in each of the two conductor portions. In this way, a gradient field of the tangential components is formed in the measurement plane and is measurable by the gradient sensor.

In other words, a new assembly is proposed in which the primary conductor is subdivided and offset in two planes above and below the sensor element of the gradient sensor without cross-paths of conductor portions. This offers significant advantages over the U-shaped assembly. For instance, only half the current flows through each conductor portion relative to the U-shaped conductor loop. Inductance is reduced, such that voltage peaks are reduced. High currents may be carried with a lower current density. Current density may be reduced by around 50% over a U-shaped current loop.

With high-frequency current components, a skin effect occurs, which results in a current density concentration close to the conductor surface. In addition, a proximity effect has the effect that a current flow arises at the inner sides of a conductor relative to a neighbouring conductor, wherein in the case of a U-shaped conductor loop this results in the two effects being superimposed, leading to high current density in the inner regions of the legs and in particular at the bending edges. This is markedly reduced by the configuration of the conductor portions according to the invention, meaning that use is feasible both at high current intensities and with high frequency components. This may be advantageous in the case in particular of multiple converter operation, in which a converter is operated at relatively high switching frequency. A sensor according to the invention may also supply a more precise measurement result and achieve higher accuracy in the case of current monitoring tasks regarding short-circuiting or overload due to the high edge steepness of the current. The field gradient is also halved according to the invention relative to the previous U-leg solution, such that the dynamic range or measurement range of the gradient sensor may be reduced. Finally, a premagnetisation field, which serves in the gradient sensor in adjustment of a linear measurement range, may advantageously be used, while in the previous U-leg solution the magnetic field arising interfered with, i.e. strengthened or weakened, the premagnetisation/bias field.

The magnetoresistive gradient sensor may in this case be formed of a gradient circuit of magnetoresistive resistor elements of an individual sensor assembly.

The proposed configuration markedly reduces the skin and proximity effects by dividing the current conductor, wherein the two partial currents flow in the same direction with regard to the measurement plane. A previous U-shaped conductor loop gives rise to a very high current density in the inner legs, resulting in very strong magnetic fields around the inner legs. For this reason, the magnetoresistive gradient sensor quickly reaches saturation, in particular in the case of high-frequency alternating currents. In contrast, a low current density arises in the inner regions of the two conductor portions. Thus, weaker magnetic fields are brought about in the inner regions of the two conductor portions. By halving the gradient field, the measurement range of the magnetoresistive gradient sensor of the current sensor assembly according to the invention is doubled with the same primary current, such that the current sensor assembly according to the invention can be used both at high current intensities and at high frequency ranges. In particular, the current sensor assembly according to the invention may be used in multiple converter operation, wherein a converter is operated at a higher switching frequency than a further converter, as already proposed, for example, with bilateral current feed to a three-phase motor or a mains supply transformer.

It is moreover advantageous that the gradient field may be adjusted, by way of a corresponding geometry of the subdivided current conductor with identical current intensity, to the same value as with a U-shaped conductor loop. In the sensor structure there is a constant magnetic field, which serves in adjustment of a linear measurement range, whereas in the case of the previous U-leg solution a parasitic magnetic field which might arise would interfere with this bias field, i.e. would unintentionally strengthen or weaken the bias field. The geometry of the current sensor assembly according to the invention makes this influence generally negligible. It is moreover advantageous that the current sensor assembly according to the invention has a high step response, i.e. a rapid response on switch-on of the current, until sudden current changes are identifiable, wherein maximum currents of up to 600 Amp nominal current and around 1000 A peak current have been considered. The current sensor assembly according to the invention is therefore also highly suitable for use for short-circuit detection or current monitoring and may assume a sensor task of an electronic fuse.

Since the total current is divided into two paths, into two partial currents through the conductor portions, and a change in current direction takes place, the conductor portions may be of smaller cross-section than in the prior art, as a U-shaped current loop carries the total current. A more compact design is thus possible and a compact structure can be achieved. Shielding against capacitive injection using a Faraday cage is simple to carry out. In the case of currents over 300 A, the current conductor geometry may be used as a mechanical sensor assembly support, which is applied, for example, to a polyimide rigid flex-PCB substrate. Due to the reduced current components on both conductor portions, the insulation thicknesses and the creepage current formation characteristic of polyimide may also be used for higher currents.

Since parasitic cross-fields are suppressed in this application, it is possible, specifically in the case of high current applications, largely to dispense with flux concentrating plates, which are used to improve characteristic curve linearity in U-rails, and the markedly reduced leakage inductance leads to greater reaction times and to lower switching losses when in application. Inductive injection of sensor signal interference in the case of transient current changes can be greatly reduced, since it is possible to dispense with a conductor loop compared with a U-shaped assembly. The two conductor loops may be divided and brought together at an abrupt angle or indeed in a uniformly rounded manner. Sensor interference fields, which for example induce circulating currents in metallic layers such as heat sinks, housing plates or shielding, are also reduced, and the bandwidth and high range measurement resolution may thus even be maintained independently of frequency.

Finally, the simple geometric design enables less costly mechanical production than when providing a U-shaped conductor portion, wherein waste and material can also be saved by a smaller geometry. Temperature behaviour is also improved, since smaller substrate thicknesses can be used and the spacing increased. Current asymmetry can also be readily controlled and compensated. It has been found that a common mode operating point shift of approximately ⅓ of an AMR characteristic curve has proven acceptable, wherein this operating point shift may be compensated structurally by different distances between the sensor and the two conductor portions or a lateral offset on the substrate, or compensated mathematically in the further signal processing.

In an advantageous further development of the invention, one conductor portion can be guided below and one conductor portion above the measurement plane. A primary current is carried in the feed conductor. The conductor portions subdivide the current in accordance with their cross-sectional ratios and conductances and carry it in the same direction with regard to the arrangement of the magnetoresistive gradient sensor. Both current components in each case bring about a magnetic field surrounding the conductor portion, wherein the magnetic fields meet on the measurement plane at the location of the gradient sensor. Each magnetic field may be broken down into two components, wherein a tangential component lies in the measurement plane and the normal component lies perpendicular to the measurement plane. The tangential component lying in the measurement plane is detected by the magnetoresistive gradient sensor. The magnetic field components of the two magnetic fields lying perpendicular to the measurement plane oppose one another and at least partially cancel each other out. The magnetoresistive gradient sensor is thus only subject to the tangential components which lie in the measurement plane and is unaffected by parasitic magnetic field components.

In a further advantageous embodiment, both conductor portions may have an identical current component and an identical relative distance from the measurement plane and from the magnetoresistive gradient sensor. It is proposed in this embodiment that the current conductor be separated into two conductor portions and, on passage of current, the current be subdivided into two identical current components, wherein each current component is carried through the conductor portion in the same direction with regard to the measurement plane. A magnetoresistive gradient sensor arranged on a board is provided between the conductor portions, which sensor measures the magnetic fields extending in the opposite direction with regard to the magnetoresistive gradient sensor. The gradient sensor is here arranged substantially at the midpoint of a diagonal connecting section between the current density neutral point of the two conductor portions, and its measurement plane is arranged at an angle to the connecting distance in such a way that the tangential components fit with a magnetic field detection range of the gradient sensor for detecting a desired current intensity range. Angles of between 0° and 90° relative to the connecting section, in particular an angular range between 30° and 60°, preferably 45°, are feasible here. Each conductor portion is thus arranged at an identical distance from the magnetoresistive gradient sensor, in particular from the measurement plane. The two magnetic fields may in each case also be broken down into two magnetic components, wherein the two tangential components lying in the measurement plane form a gradient field which is measured by the magnetoresistive gradient sensor, and the two normal components lying perpendicular to the measurement plane are subdivided. The two components lying perpendicular to the measurement plane here have no influence on current measurement.

In a further advantageous embodiment, the two conductor portions may have a non-identical current component and/or a non-identical relative distance from the measurement plane and from the magnetoresistive gradient sensor, wherein either the non-identical current component and/or the non-identical distance may compensate one another in this way or correction of the measured current value may be compensated by means of a correction factor or correction characteristic. It is proposed in this embodiment that both conductor portions be configured with different conductances. The current carried in the primary conductor is thus subdivided into two different current components. As a result of the current or magnetic field asymmetry, a spatial asymmetry is required such that the tangential components have approximately identical magnitudes at the location of the gradient sensor. This may be achieved by the distance between the magnetoresistive gradient sensor and the conductor portion with a smaller current component being less than the distance between the magnetoresistive gradient sensor and the conductor portion with the larger current component. The non-identical current components may thus be compensated by a spatial arrangement asymmetry, in particular by non-identical spacing between the conductor portions. The gradient sensor assembly may furthermore take the form of a “piggy-back” arrangement, i.e. the gradient sensor, which is regularly integrated in an IC housing, is introduced overhead. Spatial asymmetry of the gradient sensor assembly is thus achieved, wherein the position of the measurement plane can be modified in relation to the current conductor assembly and a carrier board/film. The current asymmetry may be substantially compensated by the spatial asymmetry of the gradient sensor assembly.

It is alternatively conceivable for both conductor portions to have a non-identical current component and an identical relative distance from the magnetoresistive gradient sensor. A correction factor or correction characteristic may be used to correct the measured current value, i.e. a non-identical magnitude of the tangential component. It is possible in this way to compensate spatial asymmetry or current asymmetry by a correction characteristic or a correction factor which may in particular be selected as a function of current intensity. As a result, integration under structurally difficult conditions and subsequent calibration of current measurement are particularly straightforward to achieve.

In a further advantageous embodiment, the magnetoresistive gradient sensor can be arranged on a flexible PCB film. In this embodiment, the PCB film takes the form of a substrate or circuit carrier of the current sensor assembly. A PCB film is thermally and chemically stable, flame resistant, electrically non-conductive, superhydrophobic and flexibly shaped. It makes it possible, in the case of current measurement with a compact, space-saving structure of the current conductor assembly, for the arrangement of the gradient sensor between the current conductors to be spatially varied. The magnetoresistive gradient sensor may thus be flexibly introduced and oriented in the slot of the current conductor. It is furthermore advantageous for the current conductor assembly to have small dimensions, such that, with its compact structure, the current conductor assembly can be inexpensively produced and mounted.

In a further advantageous embodiment, both conductor portions may be symmetrically height-offset relative to a measurement plane of the magnetoresistive gradient sensor, wherein one conductor portion extends below and one conductor portion above the measurement plane. It is proposed in this embodiment that both conductor portions be height-offset relative to the measurement plane of the magnetoresistive gradient sensor and that both have an identical relative distance from the measurement plane. The two conductor portions are preferably provided with identical resistances, i.e. conductances. In an alternative variant, the resistances of the two conductor portions are made non-identical, such that two non-identical current components are formed in the two conductor portions. Measured current values may be corrected by a correction factor or a correction characteristic, wherein current asymmetry may be compensated.

In a further advantageous embodiment, both conductor portions may be asymmetrically height-offset relative to a measurement plane of the magnetoresistive gradient sensor, wherein one conductor portion extends below and one conductor portion above the measurement plane. In the case of non-identical passage of current in the two conductor portions, it is furthermore advantageous to height-offset both conductor portions asymmetrically relative to the measurement plane of the magnetoresistive gradient sensor, wherein one conductor portion extends below and one conductor portion above the measurement plane. The two conductor portions are thus arranged below and above the measurement plane and have a non-identical relative distance from the measurement plane. The magnetoresistive gradient sensor is thus arranged closer to the conductor portion which carries the smaller current component, i.e. the relative distance between the measurement plane and the conductor portion with the smaller current component is less than the distance between the measurement plane and the conductor portion with the larger current component. The distance from the geometric centre point of the current density distribution of the conductor portions is essential here, wherein the spatial configuration of the conductor portion may in simplified manner be replaced by a linear conductor with radius 0 which generates a substantially identical magnetic field. The non-identical current components may be compensated in this manner. The gradient field brought about by the two current components may be precisely measured.

In a further advantageous embodiment, both conductor portions may lie in a common conductor plane and the magnetoresistive gradient sensor may be arranged at an angle β of between 0° and 90°, in particular at an angle β of between 30° and 60°, in particular of 45° to the conductor plane in which both conductor portions lie. The conductor plane is to this end the plane which passes through the two parallel guided conductor portions and a right-angled connecting line between the geometric centre points of the current densities of the conductor portions. In this embodiment, the two conductor portions and the magnetoresistive gradient sensor are not arranged parallel to one another, but instead arranged tilted relative to one another, preferably tilted by 45° to one another. The two conductor portions may have identical or also different current components. In the case of identical current components, the two conductor portions are preferably arranged symmetrically relative to the measurement plane of the magnetoresistive gradient sensor, wherein the magnetoresistive gradient sensor is arranged at an angle β to the conductor plane. Alternatively, the two conductor portions may have a non-identical current component. It is here advantageous for the magnetoresistive gradient sensor to lie at an angle β to the conductor plane and for both of the conductor portions to be arranged asymmetrically relative to the measurement plane of the magnetoresistive gradient sensor, wherein the magnetoresistive gradient sensor lies closer to the conductor portion which carries the smaller current component. A current intensity range to be measured can be adjusted to the magnetic field measurement range of the gradient sensor by varying the angle β.

In a further advantageous embodiment, the two conductor portions may be formed by at least one jumper wire and a bus bar, wherein the jumper wire is electrically contacted with the bus bar. This embodiment may consider the individual bus bar which has a jumper wire or a plurality of jumper wires for bridging, such that the two conductor portions are formed by the jumper wire and the bus bar. The jumper wire is here electrically contacted with the bus bar, wherein the jumper wire takes the form of a bypass. The bus bar may be arranged on a PCB film or a PCB conductor track. The jumper wire may furthermore consist of a bundle of conductors or bonding wires. The conductor portion of the bus bar bypassed by the jumper wire may be reduced in cross-section and will regularly carry a smaller current component than the bus bar, such that an asymmetric position of the gradient sensor closer to the jumper wire than to the bus bar is feasible and/or a correction by a (nonlinear) weighting by means of a correction factor or correction characteristic or performance map is feasible. The above-stated bus bar may furthermore have a recess for fastening the jumper wire or a region of reduced electrical conductivity, whereby adjustable current asymmetry and magnetic field asymmetry are obtained. Spatial asymmetry of the current sensor assembly is advantageous for cancelling out current asymmetry and magnetic field asymmetry, wherein the magnetoresistive gradient sensor may be arranged closer to the conductor portion in which the smaller current component flows, such that the current asymmetry is compensated. Current differences of below 10%, preferably of below 5%, in particular of below 1.5% may here also be tolerated.

In a further advantageous embodiment, the conductor portions may take the form of a stamped bent part which has a slot in which the magnetoresistive gradient sensor is arranged. In this embodiment, the subdivided conductor may be produced in one-piece from a stamped bent part which has a slot for defining the conductor portions. The slotted portions here extend as conductor portions in each case bent downwards and upwards from the conductor plane parallel to the conductor plane; alternatively, the gradient sensor may be arranged tilted between the conductor portions. The magnetoresistive gradient sensor may be arranged on a flexible PCB film between the slotted portions. The magnetoresistive gradient sensor may thus be spatially variably introduced into the slot of the stamped bent part. Alternatively to the above-stated embodiment, the conductor portions may also be of multipart construction, for example two identical stamped parts. The two identical stamped parts may be connected together by two spacers, for example soldered, riveted or welded, wherein the second stamped part may be rotated by 180° to the first stamped part. It is also conceivable to construct such conductor portions in such a manner that a straight rail has an appropriate milled portion and thus the conductor portions may be provided.

In a further advantageous embodiment, the two conductor portions may be formed by two bundles of generally flexible conductor strands, wherein these consist of thin individual wires and so form a readily bendable electrical conductor. This embodiment considers a subdivided stranded conductor, wherein two strand bundles define the two subdivided current paths as conductor portions. The magnetoresistive gradient sensor may for example be arranged on a PCB film and the gradient sensor may thus be inserted between the subdivided current paths. The two current paths may take the form of two strand bundles with an identical resistance. Two identical current components may thus be carried in the two conductor portions. With regard to the measurement plane, the magnetoresistive gradient sensor may be height-offset symmetrically to the two conductor portions.

Alternatively, this current sensor assembly may comprise two conductor portions with non-identical resistances, i.e. a non-identical quantity of fine wires per strand bundle. Passage of current through these current conductors gives rise to a non-identical current component in the two conductor portions. Current asymmetry may here be cancelled out by spatial current sensor assembly asymmetry, wherein a correspondingly smaller distance is provided between the magnetoresistive gradient sensor and the conductor portion with the smaller current component. It is conceivable to this end for the current asymmetry to be compensable by a correction factor or a correction characteristic.

In a further advantageous embodiment, the conductor portions may take the form of a parallel slotted tube with two slots, wherein the magnetoresistive gradient sensor may preferably be arranged at an angle to the slots. In this embodiment, a common conductor plane is formed at right angles to the conductor strands. It is here advantageous to tilt the gradient sensor relative to the slotted tube, such that a gradient field can be measured. The slotted tube is here arranged symmetrically relative to the measurement plane of the gradient sensor. It may preferably be considered to arrange the gradient sensor on a PCB film. The gradient sensor may thus move flexibly in the slot depending on the measured magnetic field position.

In a further advantageous embodiment, magnetic shielding may be provided, wherein the magnetic shielding substantially completely surrounds the conductor portions and the magnetic shielding preferably takes the form of two semicircular or angled iron or steel tube halves. This magnetic shielding shields the magnetoresistive gradient sensor from external influences, for example interference fields or a further line in the vicinity in a multiphase arrangement, such that a slight influence on the gradient sensor enclosed in the interior is obtained. The magnetic shielding is based on the elevated permeability of ferromagnetic substances. The flux lines of an external magnetic field readily enter bodies made from ferromagnetic substances and then run within said body before emerging once again, wherein the region enclosed by the shielding remains virtually field-free. As a result of the hollow magnetic shielding, no magnetic flux lines get into the interior of the magnetic shielding, wherein the magnetic shielding takes the form of two semicircular or rectangular iron tube halves. If magnetic field-sensitive components are arranged in the immediate vicinity of the current measuring structure, the external shielding means that only small fields occur.

Finally, a further advantageous embodiment proposes that, with regard to a three- or multiphase system, three or a plurality of magnetoresistive gradient sensors can be arranged on a common board, preferably a PCB film. Each current phase is here subdivided into two conductor portions in each case extending above and below the board, wherein the conductor portions of each current phase preferably lie in a common conductor plane, and the conductor planes of different current phases are arranged height-offset and laterally offset to one another, and in particular the board is guided at an angle between the conductor portions of the conductor planes. Because the current sensor assembly is tilted, it is possible provide a compact arrangement and space-saving measurement of all phases.

Furthermore, a further development of the above-stated embodiment with regard to the three- or multiphase system provides arranging three or a plurality of magnetoresistive gradient sensors not on one side but instead alternately on the front and back faces of a common board. With a structure of three or a plurality of magnetoresistive gradient sensors on the front and back faces of the common board, it is possible to provide a smaller and more compact current sensor assembly for the three- or multiphase system. Thanks to such a structure of the current sensor assembly, wherein three or a plurality of magnetoresistive gradient sensors are arranged alternately on the front and back faces of the common board, it is possible to improve the quality of measurement since, while obtaining the same spatial dimensions as for the current sensor assembly in which the three or a plurality of magnetoresistive gradient sensors are arranged on one side of the common board, the signal-to-noise ratio relative to the adjacent phases is higher. The conductor portions of the three current conductors may accordingly be closer together and cancel each other out to form common mode fields.

### BRIEF DESCRIPTION OF THE DRAWINGS

Further advantages are revealed by the present description of the drawings. The drawings show exemplary embodiments of the invention. The drawings, description and claims contain numerous features in combination. A person skilled in the art will expediently also consider the features individually and combine them into meaningful further combinations.

In the drawings:

FIG. 1 is a drawing showing an assembly with a U-shaped current conductor according to the prior art;

FIG. 2a is a schematic representation of current measurement according to the prior art;

FIG. 2b is a schematic representation of a first variant of current measurement according to the invention;

FIG. 2c is a schematic representation of current measurement according to a second variant of current measurement according to the invention;

FIG. 3 is a schematic representation of a first embodiment of a current sensor assembly;

FIG. 4a is a schematic representation of a second embodiment of a current sensor assembly;

FIG. 4b is a further schematic representation of current measurement according to the second embodiment;

FIG. 5a is a schematic representation of a third embodiment of a current sensor assembly;

FIG. 5b is a further schematic representation of current measurement according to the third embodiment;

FIG. 6 is a perspective view of a fourth embodiment of a current sensor assembly;

FIG. 7 is a schematic representation of a fifth embodiment of a current sensor assembly;

FIG. 8a is a schematic representation of a sixth embodiment of a current sensor assembly;

FIG. 8a is a schematic representation of a seventh embodiment of a current sensor assembly;

FIG. 9 is a schematic representation of a eighth embodiment of a current sensor assembly;

FIG. 10 is a schematic representation of a ninth embodiment of a current sensor assembly;

FIG. 11a is a schematic representation of a first variant of a tenth embodiment of a current sensor assembly;

FIG. 11b is a schematic representation of a second variant of a tenth embodiment of a current sensor assembly;

FIG. 12 is a schematic representation of an eleventh embodiment of a current sensor assembly.

Identical elements are denoted with the same reference signs in the figures. The figures merely show examples and should not be understood as being limiting.

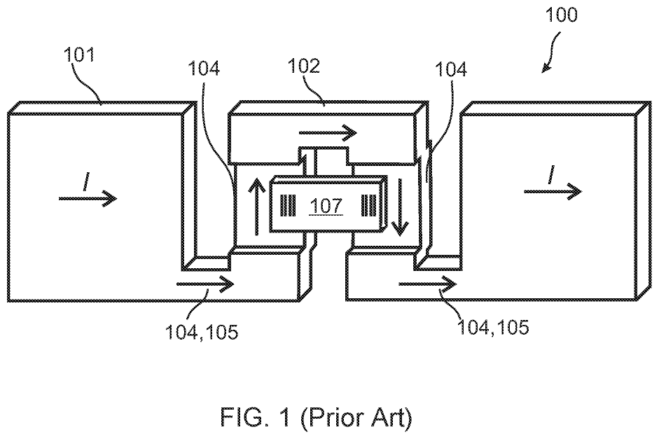

FIG. 1 shows a current measuring assembly 100 known from the prior art. The current measuring assembly 100 has a sensor element 107 and a U-shaped conductor piece 101, in which the leg 104 active in terms of current measurement is set back in a z-direction relative to the connecting web 102 parasitic in terms of current measurement and the connecting line 105, such that parasitic magnetic field components penetrate a magnetic field-neutral orientation plane of the sensor structure of the sensor element 107 substantially at right angles. The arrangement, offset in the z direction, of the legs 104 relative to the connecting lines 105 and the connecting web 102 ensures that parasitic magnetic field components are suppressed or merely pass through a magnetic field-neutral orientation plane, while the magnetic field components which are active in terms of current measurement and are to be detected pass through the magnetic field-sensitive orientation plane of the sensor element 107.

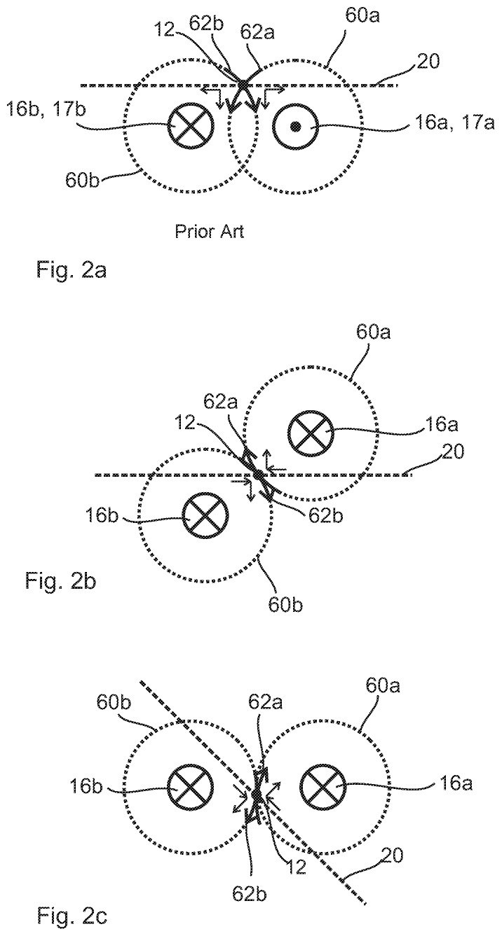

FIG. 2a shows a schematic current measurement principle from the prior art corresponding to FIG. 1. The corresponding current measuring assembly consists of a U-shaped conductor loop and a sensor element arranged in the plane parallel to the conductor loop, wherein the conductor loop has connecting lines, the legs and the connecting web. In both legs active in terms of current measurement, a current flows in the opposite direction with regard to a gradient sensor 12, wherein in one leg the current 16a flows in the direction 17a and in the other leg the current 16b flows in the direction 17b. Magnetic fields 60a, 60b are brought about in the current legs 104, wherein the magnetic fields 60a, 60b surround the legs 104. The magnetic fields 60a and 60b intersect in the measurement plane 20 in which the sensor element lies. Each magnetic field 60a, 60b may be broken down into two components, wherein a tangential component lies in the measurement plane 20 and can be measured by the sensor element, and the other normal component lies perpendicular to the measurement plane 20. The normal components of the two magnetic fields lying perpendicular to the measurement plane 20 add up and point in the same direction. In this case, the sensor element merely measures the difference between two tangential components lying in the measurement plane 20, wherein the components lying in the measurement plane are oppositely oriented and thus form a gradient field.

FIG. 2b is a schematic representation of a first variant embodiment of current measurement. The current sensor assembly according to the invention comprises a magnetoresistive gradient sensor 12, which measures a gradient field brought about in two conductor portions flowed through in parallel by current, and the two conductor portions which are height-offset relative to the measurement plane 20. The magnetoresistive gradient sensor 12 defines a measurement plane 20. The current component 16a, 16b flows in the same direction. The magnetic fields generated by the current components 16a, 16b intersect in the measurement plane 20 in opposing directions. The magnetic field 60a brought about by the conductor portion with direction 17 has a magnetic field direction 62a and the magnetic field 60b brought about by the conductor portion in direction 17b has a magnetic field direction 62b. Each magnetic field 62a, 62b can be broken down into two components. The tangential components lying in the measurement plane 20 may be measured by the magnetoresistive gradient sensor. In contrast, the normal components lying at right angles to the measurement plane 20 are resolved. By measuring the gradient field, the electric current may be determined, wherein the gradient field is provided by the difference between the two tangential magnetic field components lying in the measurement plane 20.

FIG. 2c shows a second variant embodiment of current measurement according to the invention. In this embodiment, the two conductor portions are arranged in a common conductor plane. The magnetoresistive gradient sensor is tilted at an angle relative to the conductor plane, wherein the same distance is formed between the magnetoresistive gradient sensor 12 and the two conductor portions. The current components 16a, 16b are the same size. The magnetic fields 60a, 60b are generated thereby, and each have the magnetic field direction 62a and 62b. The magnetoresistive gradient sensor 12 is arranged in the measurement plane 20, wherein the magnetic fields 60a and 60b meet in the measurement plane 20 and are measured by the magnetoresistive gradient sensor 12. The tangential components of the two magnetic fields 60a and 60b run in opposite directions with regard to the measurement plane 20 and may each be broken down into two components, wherein one tangential component lies in the measurement plane 20 and the other normal component lies at right angles to the measurement plane 20. The two tangential components lying at right angles to the measurement plane 20 are resolved and the magnetoresistive gradient sensor 12 measure the components lying in the measurement plane 20. The magnitude and frequency of the carried current may thus be determined.

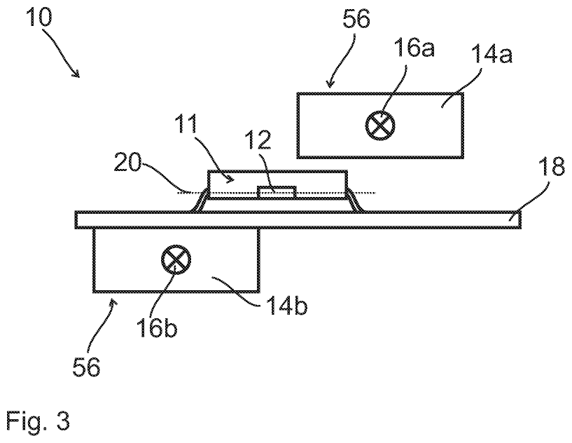

FIG. 3 shows a first embodiment of a current sensor assembly 10. A current conductor 56 is subdivided into two conductor portions 14a, 14b, wherein a corresponding current component 16a and current component 16b flow in the same current flow direction in the conductor portions 14a, 14b. A sensor element 11 on a PCB film 18 is placed between the two conductor portions 14a, 14b, wherein the sensor element 11 comprises a magnetoresistive gradient sensor 12, which measures a magnetic field strength difference of one tangential component of the magnetic field in a measurement plane 20. The measurement plane 20 is in this case defined such that magnetoresistive resistors of the gradient sensor 12 are located therein, which resistors are sensitive with regard to vector components of the magnetic field which lie parallel in the measurement plane 20 (tangential components). Furthermore, the two conductor portions 14a, 14b are height-offset antiparallel with regard to the measurement plane 20.

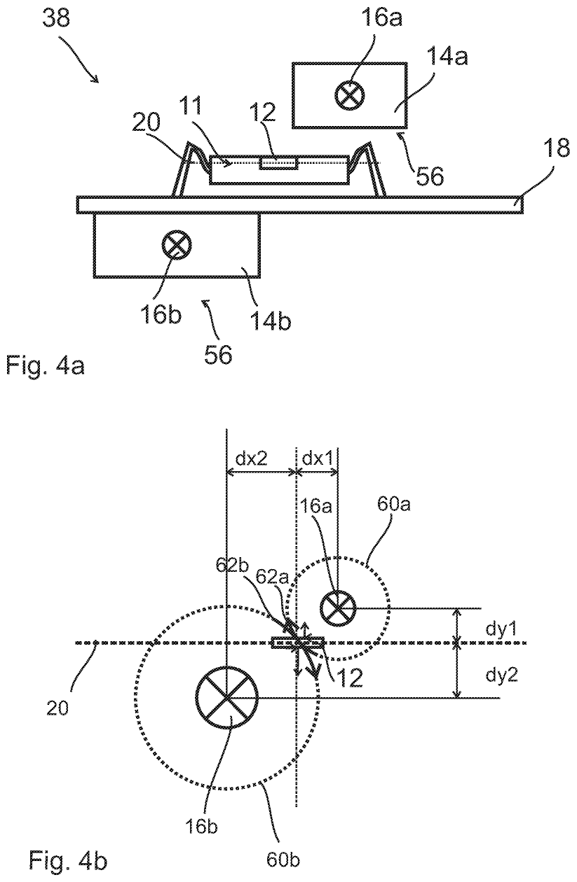

FIG. 4a shows a second embodiment of a current sensor assembly 38, which comprises two conductor portions 14a, 14b and a sensor element 11, wherein the sensor element 11 is arranged on a PCB film 18. Non-identical current components 16a and 16b flow in the corresponding conductor portions 14a, 14b. To compensate the non-identical magnitudes of the two current components, spatial asymmetry is advantageous for current measurement, wherein the spatial asymmetry by a “piggy back” arrangement of the IC housing of the sensor element 11, in which an IC substrate of the gradient sensor 12 concealed therein is selected. The “piggy back” arrangement is constructed in such a way that the IC housing of the sensor element 11 is introduced overhead, wherein the magnetoresistive gradient sensor 12 is arranged asymmetrically with the measurement plane 20 in the IC housing. In this way, the relative height of the measurement plane 20 is displaced relative to the surface of the PCB 18. An asymmetric arrangement of the measurement plane 20 may thus be achieved between the conductor portions 14a, 14b.

FIG. 4b shows current measurement in relation to the second embodiment of a current sensor assembly 38 of FIG. 4a. The two conductor portions have non-identical current components 16a, 16b, which are carried in the same current flow direction. The measurement plane 20 is defined by the arrangement and orientation of the magnetoresistive gradient sensor 12. The current in the respective conductor portion 14a and conductor portion 14b generates a magnetic field 60a and magnetic field 60b, which run in opposite directions. The distance in the x direction dx1, which corresponds to the distance between the magnetoresistive gradient sensor 12 and conductor portion 14a in the x direction, is smaller than the distance in the x direction dx2, which corresponds to the distance between the magnetoresistive gradient sensor 12 and conductor portion 14b in the x direction. In this case, the distance in the y direction dy1 is smaller than the distance in the y direction dy2, wherein the distance in the y direction dy1 corresponds to the distance between the magnetoresistive gradient sensor 12 and conductor portion 14a in the y direction, and the distance in the y direction dy2 corresponds to the distance between the magnetoresistive gradient sensor 12 and conductor portion 14b in the y direction. Due to the resultant spatial asymmetry of the current sensor assembly, the difference in current components 16a, 16b with regard to the magnitude of the tangential components may be compensated. The two magnetic fields 60a, 60b may each be broken down into two components. A tangential component lies in the measurement plane 20 and the normal component lies perpendicular to the measurement plane 20. The two normal components lying perpendicular to the measurement plane 20 may compensate on another, while a gradient between the two tangential components lying in the measurement plane 20 is measured by the magnetoresistive gradient sensor 12.

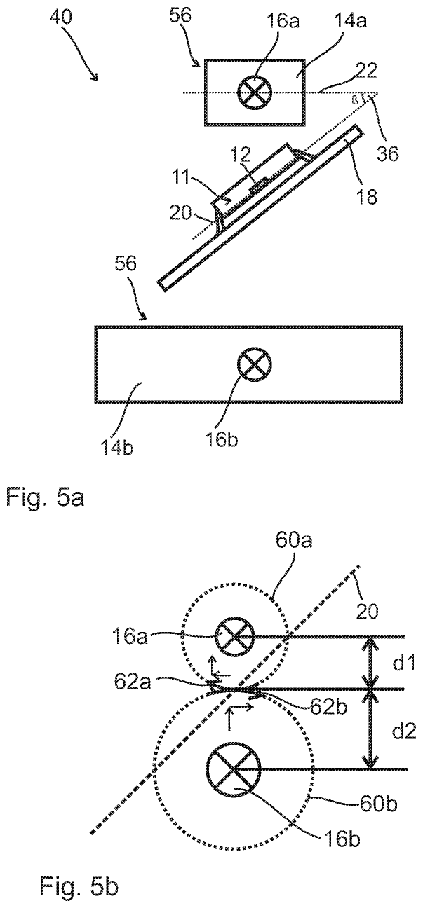

FIG. 5a shows a third embodiment of a current sensor assembly 40. The current conductor 56 is subdivided into two conductor portions 14a, 14b, which lie in a common conductor plane 22. The corresponding current component, which has an identical direction and a non-identical magnitude, is carried in both conductor portions 14a, 14b. The sensor element 11 arranged on the PCB film 18 is arranged at an angle μ 36 to the conductor plane 22, i.e. the magnetoresistive gradient sensor 12 is tilted relative to the conductor plane 22. The angle β 36 is preferably selected in a range from 30° to 60°, preferably 45°. If the current component 16a is smaller than the current component 16b, the two conductor portions 14a, 14b are arranged asymmetrically relative to the measurement plane 20. In other words, the distance between the measurement plane 20 and the conductor portion 14a may be less than the distance between the measurement plane 20 and the conductor portion 14b, whereby the magnetic field strength difference may be measured precisely by the magnetoresistive gradient sensor 12.

FIG. 5b shows a current measurement in relation to the third embodiment of a current sensor assembly 40. The two conductor portions 14, 14b are arranged in a common conductor plane, wherein the conductor portions 14a, 14b have the current component 16a and current component 16b, which have a non-identical current magnitude and are carried in the same current flow direction. The measurement plane 20 is tilted relative to the two conductor portions 14a, 14b by an angle β, wherein as a result of the current asymmetry the two conductor portions 14a, 14b are arranged asymmetrically relative to the measurement plane 20. In this embodiment, the distance d1 between the conductor portion 14a and the conductor plane 20 is less than the distance d2 between the conductor portion 14b and the conductor plane 20. The two magnetic fields 60a, 60b brought about intersect at the measurement plane 20. The magnetoresistive gradient sensor may thus measure the difference between the two magnetic fields. Optimum asymmetric orientation and the various distances relative to the conductor portions may be identified in advance during the design process by means of computer-aided field simulation or empirically by mechanical calibration for a desired current measurement range.

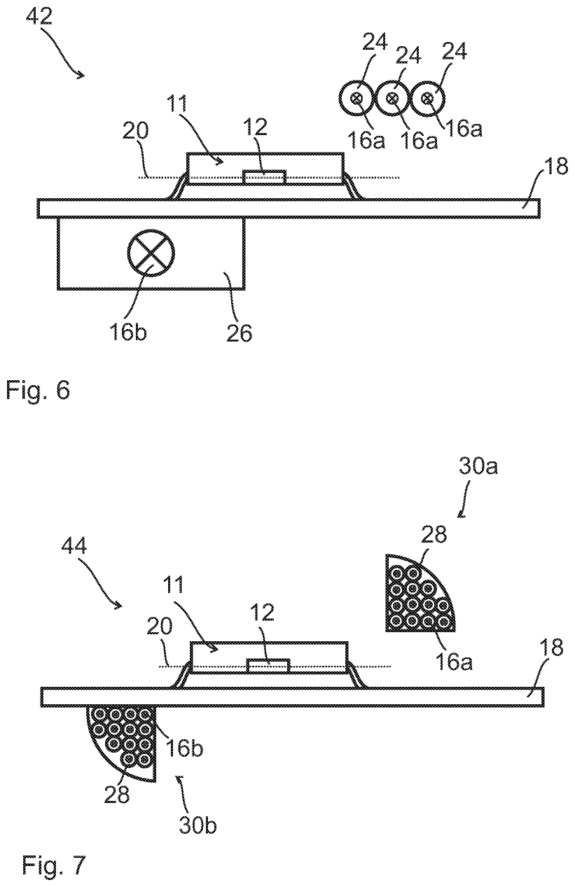

FIG. 6 shows a fourth embodiment of a current sensor assembly 42. The conductor portions are formed by three parallel guided jumper wires 24 and a solid bus bar 26. The sensor element 11 is arranged between the conductor portions on a PCB film 18 or a rigid PCB. The sensor element 11 comprises the magnetoresistive gradient sensor 12 with the measurement plane 20, wherein the magnetic field strength difference may be measured in this measurement plane 20 of the magnetoresistive gradient sensor 12. Furthermore, the current component 16a flows in the jumper wires 24 and the current component 16b in the bus bar 26, wherein current component 16a and current component 16b are identical, such that the two conductor portions are symmetrically height-offset relative to the measurement plane 20, such that an identical distance is provided between the measurement plane 20 and the two conductor portions.

FIG. 7 shows a fifth embodiment of a current sensor assembly 44. The conductor portions are formed by bundles 30a, 30b of conductor strands 28. The current component 16a, which has the same current flow direction as the current flow direction of the current component 16b in the bundle 30b, flows in the bundle 30a. The sensor element 11 is arranged between bundle 30a and bundle 30b, which sensor element comprises the magnetoresistive gradient sensor 12, such that the magnetic fields generated by the bundles 30a, 30b may be detected by the magnetoresistive gradient sensor 12 in the measurement plane 20.

The distance between the magnetoresistive gradient sensor 12 and the two bundles 30a, 30b is definable depending on the current component. With an identical current component in the two bundles 30a, 30b, the bundles 30a, 30b are arranged symmetrically relative to the measurement plane 20, in particular the magnetoresistive gradient sensor 12, i.e. a spatial symmetry of the current sensor assembly is provided. In contrast, the two bundles 30a, 30b are asymmetrically height-offset relative to the measurement plane 20, in particular the magnetoresistive gradient sensor 12 in the case of non-identical passage of current, wherein a greater distance is provided between the measurement plane 20 and the bundle which has a greater current component.

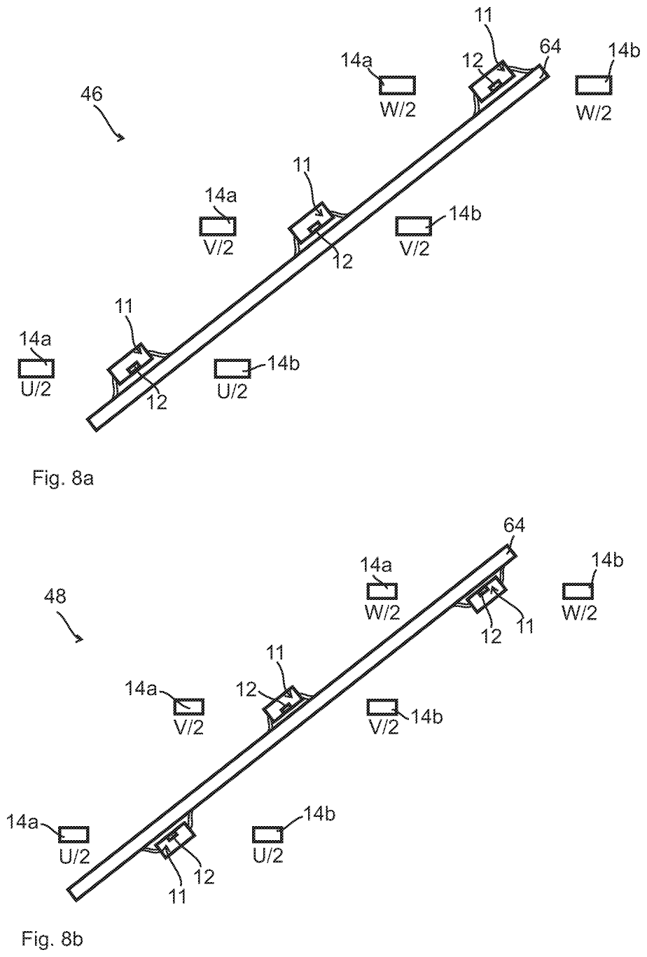

FIG. 8a shows a sixth embodiment of a current sensor assembly 46 in relation to a three-phase system. Three sensor elements 11 are arranged on a common board 64 on the top thereof, wherein each sensor element 11 comprises the magnetoresistive gradient sensor 12. In this case, each current phase U, V, W is subdivided into two conductor portions 14a, 14b, which each extend above and below the board 64. Furthermore, the conductor portions 14a, 14b of each current phase U, V, W lie in a common conductor plane, while the conductor planes of different current phases U, V, W are arranged height-offset and laterally offset. The board 64 is arranged at an angle between the conductor portions 14a, 14b of the conductor planes, such that each gradient sensor 12 is at the same distance from the conductor portions 14a, 14b associated therewith which have its current phase. In this case, three magnetoresistive gradient sensors 12 are arranged on one side of the common board 64. This compact design enables measurement of the multiphase system, which can be scaled accordingly in the case of multiple phases, e.g. a six-phase system.

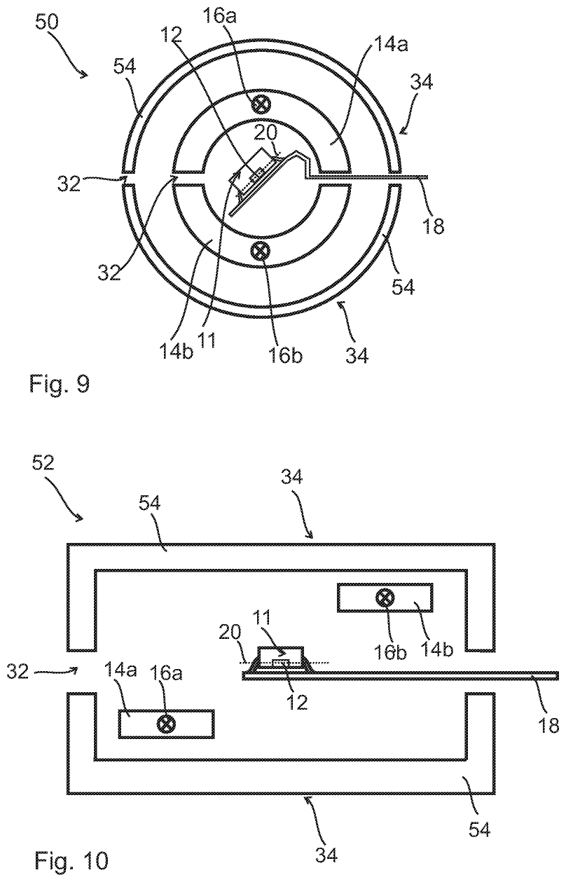

FIG. 8b shows a seventh embodiment of a current sensor assembly 48. This current sensor assembly likewise relates to a three-phase system. Three sensor elements 11 are arranged on the common board 64, wherein three sensor elements 11 in each case comprise the magnetoresistive gradient sensor 12. Each current phase U, V, W is subdivided into two conductor portions 14a, 14b, which each extend above and below the board 64. The board 64 is tilted relative to the conductor portions 14a, 14b of different current phase U, V, W. In this embodiment, three magnetoresistive gradient sensors 12 are arranged alternately on the front and back faces of the common board 64, so resulting in a more compact design of the overall system. It is advantageous, in this case, that a highly space-saving current measurement of all three phases U, V, W can be carried out with the embodiments in FIGS. 9a and 9b.

FIG. 9 shows an eighth embodiment of a current sensor assembly 50. This current sensor assembly comprises two conductor portions 14a, 14b and a sensor element 11, wherein the two conductor portions 14a, 14b take the form of a parallel slotted tube with two diagonally opposing slots 32. The two conductor portions 14a, 14b are thus arranged in a common radial plane, wherein an identical current component flows in the two conductor portions 14a, 14b. The sensor element 11 comprises the magnetoresistive gradient sensor 12 and is arranged on a PCB film 18. The magnetoresistive gradient sensor 12 may thus move within the tube and accordingly be arranged in the correct position; an arrangement on a rigid PCB is nevertheless also possible. The magnetoresistive gradient sensor 12 is arranged at an angle to the two conductor portions 14a, 14b. Current component 16a and current component 16b each generate a magnetic field. The difference in the magnetic fields which are brought about may be measured with the magnetoresistive gradient sensor 12. Furthermore, enveloping magnetic shielding 34 is provided, which takes the form of two semicircular steel tube halves 54. This magnetic shielding 34 shields the magnetoresistive gradient sensor 12 from external influences, such that a slight influence is exerted on the magnetoresistive gradient sensor 12 enclosed on the inside, and shielding is also provided for stray magnetic fields of the current conductor arising from external wiring.

FIG. 10 shows a ninth embodiment of a current sensor assembly 52. This current sensor assembly comprises two conductor portions 14a, 14b and a sensor element 11.

Arranged between the two conductor portions 14a, 14b is the sensor element 11, in which the magnetoresistive gradient sensor 12 detects the gradient field and which is arranged on the PCB film 18. The two conductor portions 14a, 14b are height-offset symmetrically and antiparallel relative to the measurement plane 20, in which the magnetic field strength difference is measured. Current component 16a and current component 16b flow in the same direction in the conductor portions 14a, 14b. Outside the current sensor assembly two rectangular steel tube halves 54 are formed as magnetic shielding 34, these having two slots 32 and providing shielding against disruptive influences in accordance with FIG. 9.

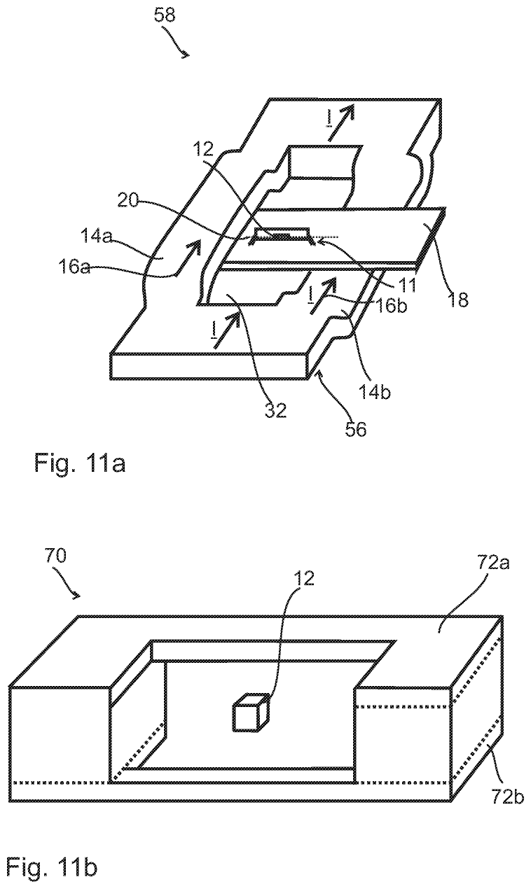

FIG. 11a shows a tenth embodiment of a current sensor assembly 58. The current conductor 56 takes the form of a one-piece stamped bent part, which is subdivided into two parts and has the slot 32, in which the sensor element 11 is arranged on the PCB film 18. In this case, the slotted portions are configured as conductor portions 14a, 14b. A primary current I flows in the current conductor 56, which primary current is subdivided into two current components 16a, 16b by the conductor portions 14a, 14b and is carried in the same direction with regard to the magnetoresistive gradient sensor 12. As a result of the flexible PCB film 18, the magnetoresistive gradient sensor 12 may be introduced in spatially variable manner into the slot 32 in the current conductor 56.

FIG. 11b shows an eleventh embodiment of a current sensor assembly 70. In contrast to FIG. 11a, the current conductor takes the form of two stamped bent parts connected together. The stamped bent part 72a and the stamped bent part 72b are soldered together, riveted together or welded, such that the two stamped bent parts may be connected together, and optionally spaced by spacers, which define a spatial distance from the measurement plane 20. In this way, the stamped bent parts may be provided as two conductor portions. The two stamped bent parts are configured antiparallel to one another, and the magnetoresistive gradient sensor 12 may optionally be arranged tilted relative to the two stamped bent parts, preferably by 45° relative to the two stamped bent parts, in order to adapt the measurement plane to the magnetic field profile. The primary current may thereby be measured.

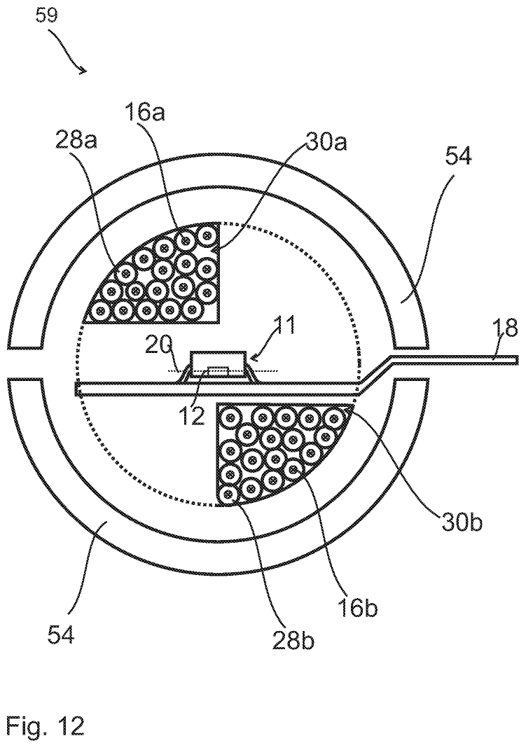

FIG. 12 shows a twelfth embodiment of a current sensor assembly 59. The two conductor portions take the form of two bundles 30a, 30b, which are formed of conductor strands 28a, 28b. The current component 16a flowing in the bundle 30a generates a magnetic field, which is detected in the measurement plane 20 by means of the magnetoresistive gradient sensor 12 of the sensor element 11. In addition, the magnetic field, which is generated by the current component 30b, is simultaneously measured in the measurement plane 20 by means of the magnetoresistive gradient sensor 12. The difference between the tangential magnetic field strength components lying in the measurement plane 20 may thus be determined which provide an insight into the total current. Furthermore, magnetic shielding is provided, which takes the form of two semicircular steel tube halves 54. Since the sensor element 11 is arranged on the PCB film, the sensor element 11 or the magnetoresistive gradient sensor 12 may be arranged in spatially variable manner.

### LIST OF REFERENCE SIGNS

10 First embodiment of a current sensor assembly
11 Sensor element
12 Magnetoresistive gradient sensor
14a Conductor portion a
14b Conductor portion b
16a Current component a
16b Current component b
17a Direction a
17b Direction b
18 PCB film
20 Measurement plane
22 Conductor plane
24 Jumper wire
26 Bus bar
28 Conductor strand
30a Bundle a
30b Bundle b
32 Slot
34 Magnetic shielding
36 Angle β
38 Second embodiment of a current sensor assembly
40 Third embodiment of a current sensor assembly
42 Fourth embodiment of a current sensor assembly
44 Fifth embodiment of a current sensor assembly
46 Sixth embodiment of a current sensor assembly
48 Seventh embodiment of a current sensor assembly
50 Eighth embodiment of a current sensor assembly
52 Ninth embodiment of a current sensor assembly
54 Steel tube half
56 Current conductor
58 Tenth embodiment of a current sensor assembly
59 Twelfth embodiment of a current sensor assembly
d1 Distance between conductor portion a and measurement plane d2 Distance between conductor portion b and measurement plane 60a
60b Magnetic field a
60b Magnetic field b
62a Magnetic field direction a
62b Magnetic field direction b
64 Common board
I Primary current
66 Feed conductor
68 Board
70 Eleventh embodiment of a current sensor assembly 72a U-shaped stamped bent part a
72b U-shaped stamped bent part b
100 Current measuring assembly
101 Conductor piece
102 Connecting web
104 Leg
105 Connecting line
107 Sensor element
dx1, dx2 Distance in the x direction dy1, dy2 Distance in the y direction d1, d2 Distance
U, V, W Current phase

1. A current sensor assembly comprising:
a magnetoresistive gradient sensor arranged between two conductor portions of a current conductor, the conductor portions subdividing the current and carrying it in the same direction with regard to the arrangement of the magnetoresistive gradient sensor, and the conductor portions being height-offset with regard to a measurement plane of the magnetoresistive gradient sensor; one conductor portion being guided below and one conductor portion above the measurement plane.

2. A current sensor assembly according to claim 1, wherein both the conductor portions have an identical current component and an identical relative distance from the measurement plane and from the magnetoresistive gradient sensor.

3. A current sensor assembly according to claim 1, wherein both conductor portions have a non-identical current component and/or a non-identical relative distance from the measurement plane and from the magnetoresistive gradient sensor, wherein either the non-identical current component and the non-identical distance compensate one another or a correction of the measured current value can be carried out by means of a correction factor or correction characteristic.

4. A current sensor assembly according to claim 1, wherein the magnetoresistive gradient sensor is arranged on a flexible PCB film.

5. A current sensor assembly according to claim 1, wherein both conductor portions are symmetrically height-offset relative to a measurement plane of the magnetoresistive gradient sensor, wherein one conductor portion extends below and one conductor portion above the measurement plane.

6. A current sensor assembly according to claim 1, wherein both conductor portions are asymmetrically height-offset relative to a measurement plane of the magnetoresistive gradient sensor, wherein one conductor portion extends below and one conductor portion above the measurement plane.

7. A current sensor assembly according to claim 1, wherein both conductor portions lie in a common conductor plane and the magnetoresistive gradient sensor is arranged at an angle β of between 0° and 90° to the conductor plane in which the two conductor portions lie.

8. A current sensor assembly according to claim 1, wherein both conductor portions are formed by at least one jumper wire and a bus bar, wherein the jumper wire is electrically contacted with the bus bar.

9. A current sensor assembly according to claim 1, wherein the conductor portions take the form of a stamped bent part which has a slot in which the magnetoresistive gradient sensor is arranged.

10. A current sensor assembly according to claim 1, wherein both conductor portions are formed by two bundles of conductor strands.

11. A current sensor assembly according to claim 1, wherein the conductor portions take the form of a parallel slotted tube with two slots and the magnetoresistive gradient sensor is preferably arranged at an angle to the slots.

12. A current sensor assembly according to claim 1, wherein magnetic shielding comprising one of the conductor portions is provided, which shielding preferably takes the form of two semicircular or rectangular steel tube halves.

13. A current sensor assembly according to claim 1, wherein with regard to a three- or multiphase system, three or a plurality of magnetoresistive gradient sensors are arranged on a common board and each current phase is subdivided into two conductor portions in each case extending above and below the board, wherein the conductor portions of each current phase lie in a common conductor plane, and the conductor planes of different current phases are arranged height-offset.

14. A current sensor assembly according to claim 13, wherein with regard to a three- or multiphase system, three or a plurality of magnetoresistive gradient sensors are arranged on one side of or alternately on the front and back faces of the common board.

15. A current sensor assembly according to claim 7, wherein the angle β is between 30° and 60°.

16. A current sensor assembly according to claim 15, wherein in angle β is 45°.

17. A current sensor according to claim 13, wherein the common board is a PCB film.

18. A current sensor according to claim 13, wherein the common board is arranged at an angle between the conductor portions of the conductor planes.
